(19) United States
(12) Patent Application Publication
(10) Pub. No.: US 2024/0243102 A1
(43) Pub. Date: Jul. 18, 2024

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Yikoan Hong, Suwon-si (KR); Seokho Kim, Suwon-si (KR); Kwangjin Moon, Suwon-si (KR)

(73) Assignee: SAMSUNG ELECTRONICS CO., LTD., Suwon-si (KR)

(21) Appl. No.: 18/410,644

(22) Filed: Jan. 11, 2024

(30) Foreign Application Priority Data
Jan. 16, 2023 (KR) 10-2023-0006318

(51) Int. Cl. H01L 25/065; H01L 23/00; H01L 23/31; H01L 23/498; H01L 23/544; H10B 80/00

(52) U.S. Cl. CPC H01L 25/0657; H01L 23/3135; H01L 23/49822; H01L 23/544; H01L 24/16; H01L 24/32; H01L 24/73; H01L 24/96; H01L 24/97; H10B 80/00; H01L 24/08; H01L 2223/5446; H01L 2224/08225; H01L 2224/16148; H01L 2224/32145; H01L 2224/73204; H01L 2224/96; H01L 2224/97; H01L 2225/06513; H01L 2225/06541; H01L 2225/06555; H01L 2924/1431; H01L 2924/1436; H01L 2924/1811

(57) ABSTRACT

Provided is a semiconductor package including a first semiconductor chip, at least one second semiconductor chip on a top surface of the first semiconductor chip, a molding layer on the at least one second semiconductor chip, and a marking layer on at least one side of the molding layer, the marking layer including a hydrophobic material, wherein inner sidewalls of the marking layer contact a lower portion of sidewalls of the molding layer.

### CROSS-REFERENCE TO RELATED APPLICATIONS

This application is based on and claims priority to Korean Patent Application No. 10-2023-0006318, filed on Jan. 16, 2023, in the Korean Intellectual Property Office, the disclosure of which is incorporated by reference herein in its entirety.

### BACKGROUND

Embodiments of the present disclosure relate to a semiconductor package and a method of manufacturing the same, and more particularly, to a semiconductor package including a plurality of vertically stacked semiconductor chips and a method of manufacturing the same.

According to the rapid development of the electronic industry and demands of users, semiconductor packages mounted on electronic products are demanded to provide high performance and include various functions, and thus a semiconductor package including a plurality of semiconductor chips has been proposed. Also, to reduce the size of a semiconductor package including a plurality of semiconductor chips, a semiconductor package in which a plurality of semiconductor chips are vertically stacked is being developed.

### SUMMARY

One or more embodiments provide a semiconductor package including a plurality of vertically stacked semiconductor chips capable of realizing miniaturization and high performance.

According to an aspect of an embodiment, there is provided a semiconductor package including a first semiconductor chip, at least one second semiconductor chip on a top surface of the first semiconductor chip, a molding layer on the at least one second semiconductor chip, and a marking layer on at least one side of the molding layer, the marking layer including a hydrophobic material, wherein inner sidewalls of the marking layer contact a lower portion of sidewalls of the molding layer.

According to another aspect of an embodiment, there is provided a semiconductor package including a first semiconductor chip, a plurality of second semiconductor chips on a top surface of the first semiconductor chip, a marking layer on peripheral regions of the top surface of the first semiconductor chip, surrounding the plurality of second semiconductor chips when viewed in a plan view, and spaced apart from the plurality of second semiconductor chips, and a molding layer on the plurality of second semiconductor chips and including sidewalls contacting inner sidewalls of the marking layer, wherein a level of a top surface of the marking layer is lower than a level of the top surface of the molding layer in a vertical direction.

According to another aspect of an embodiment, there is provided a semiconductor package including a redistribution layer (RDL) interposer, a buffer chip including a first substrate and a plurality of first through electrodes at least partially penetrating through the first substrate, an active surface of the first substrate facing the RDL interposer and in contact with the RDL interposer, a plurality of memory cell chips respectively including a second substrate and a plurality of second through electrodes at least partially penetrating through the second substrate, the plurality of memory cell chips being sequentially on the buffer chip, such that an active surface of the second substrate faces the buffer chip, a plurality of front surface connection pads on bottom surfaces of the plurality of memory cell chips, a plurality of rear surface connection pads on an inactive surface of the first substrate and an inactive surface of the second substrate, a plurality of chip connection terminals between the plurality of front surface connection pads and the plurality of rear surface connection pads, an insulating adhesive layer between the buffer chip and the plurality of memory cell chips, a molding layer surrounding the plurality of memory cell chips and the insulating adhesive layer, and a marking layer on at least one side of the molding layer on the buffer chip and including a hydrophobic material.

### BRIEF DESCRIPTION OF DRAWINGS

Embodiments will be more clearly understood from the following detailed description taken in conjunction with the accompanying drawings in which:

FIG. 1 is a plan view of a semiconductor package according to embodiments:

FIG. 2 is a schematic cross-sectional view of the semiconductor package of FIG. 1:

FIG. 3 is an enlarged view of a portion A1 of FIG. 2:

FIG. 4 is a plan view of a semiconductor package according to embodiments:

FIG. 5 is a cross-sectional view of the semiconductor package of FIG. 4:

FIG. 6 is a plan view of a semiconductor package according to embodiments:

FIG. 7 is a plan view of a semiconductor package according to embodiments:

FIG. 8 is a plan view of a semiconductor package according to embodiments:

FIG. 9 is a plan view of a semiconductor package according to embodiments:

FIG. 10 is a plan view of a semiconductor package according to embodiments:

FIG. 11 is a plan view of a semiconductor package according to embodiments:

FIG. 12 is a cross-sectional view of the semiconductor package of FIG. 11:

FIGS. 13, 14, 15, 16, 17A, 17B, 18, 19, and 20 are schematic diagrams showing a method of manufacturing a semiconductor package according to embodiments, wherein, in detail, FIGS. 13 to 16, 17A, and 18 to 20 are cross-sectional views according to a process sequence, and FIG. 17B is a plan view corresponding to FIG. 17A: and

FIGS. 21, 22, and 23 are cross-sectional views showing a method of manufacturing a semiconductor package according to embodiments.

### DETAILED DESCRIPTION

Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

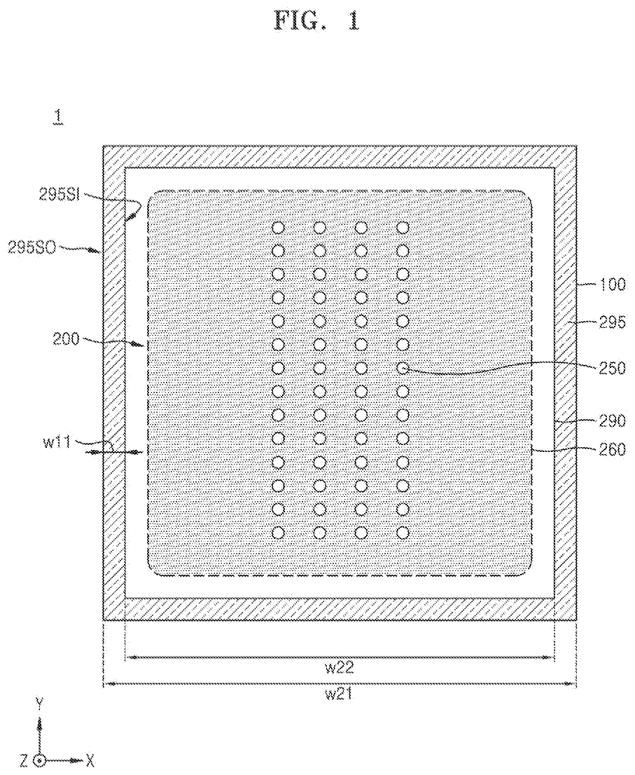

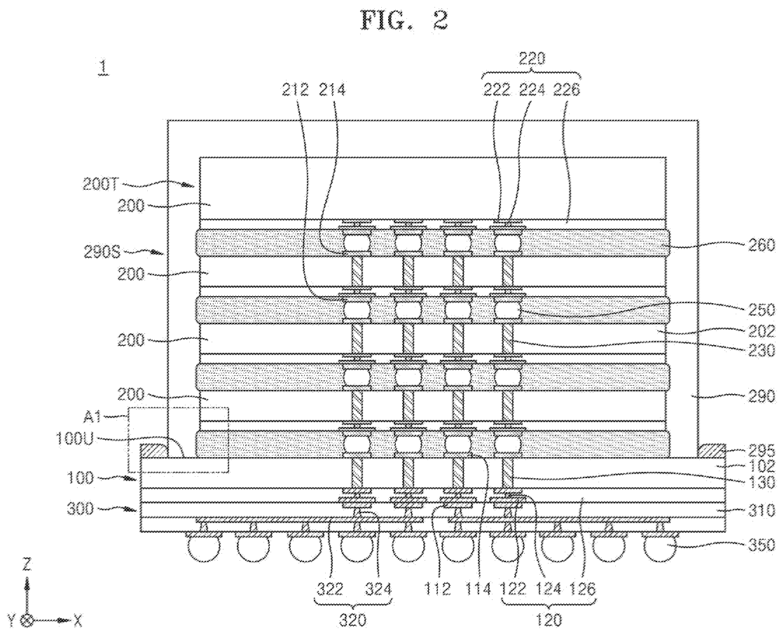

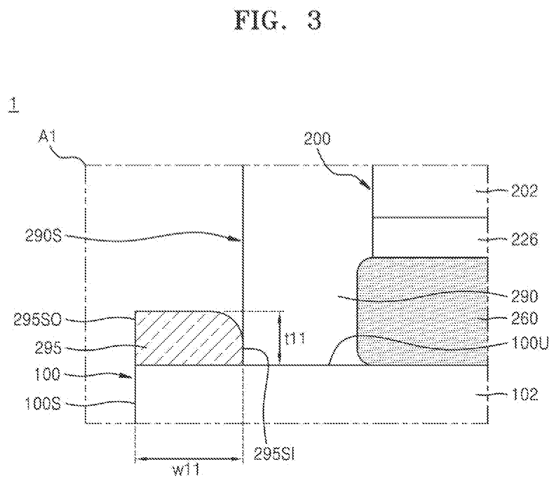

FIG. 1 is a plan view of a semiconductor package 1 according to embodiments. FIG. 2 is a schematic cross-sectional view of the semiconductor package 1. FIG. 3 is an enlarged view of a portion A1 of FIG. 2.

Referring to FIGS. 1 to 3, the semiconductor package 1 may include an interposer 300, a first semiconductor chip 100 disposed on the interposer 300, a plurality of second semiconductor chips 200 stacked on the first semiconductor chip 100, a molding layer 290 surrounding the plurality of second semiconductor chips 200, and a marking layer 295 disposed on edges at peripheral regions of the top surface of the first semiconductor chip 100 surrounding the molding layer 290 when viewed in a plan view.

Although FIG. 2 shows that the semiconductor package 1 includes one first semiconductor chip 100 and four second semiconductor chips 200, embodiments are not limited thereto. For example, the semiconductor package 1 may include two or more second semiconductor chips 200. In some embodiments, the number of second semiconductor chips 200 included in the semiconductor package 1 may be a multiple of 4. The plurality of second semiconductor chips 200 may be sequentially stacked on the first semiconductor chip 100 in a vertical direction. The first semiconductor chip 100 and the plurality of second semiconductor chips 200 may each be sequentially stacked with active surfaces of each of the plurality of second semiconductor chips 200 facing downward, that is, toward the interposer 300.

According to some embodiments, the interposer 300 may be a redistribution layer (RDL) interposer. The interposer 300 may include at least one redistribution insulation layer 310 and a plurality of redistribution patterns 320. The plurality of redistribution patterns 320 may include a plurality of redistribution line patterns 322 and a plurality of redistribution vias 324. According to some embodiments, the interposer 300 may include a plurality of stacked redistribution insulation layers 310. The redistribution insulation layer 310 may include, for example, photo imageable dielectric (PID) or photosensitive polyimide (PSPI). The plurality of redistribution patterns 320 composed of the plurality of redistribution line patterns 322 and the plurality of redistribution vias 324 may include, for example, a metal like copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto. According to some embodiments, the plurality of redistribution patterns 320 may be formed by stacking a metal or a metal alloy on a seed layer including, for example, titanium, titanium nitride, or titanium tungsten.

A plurality of redistribution line patterns 322 may be arranged on at least one of the top surface and the bottom surface of the redistribution insulation layer 310. A plurality of redistribution vias 324 may penetrate through at least one redistribution insulation layer 310 and contact portions of the plurality of redistribution line patterns 322, respectively. According to some embodiments, some of the plurality of redistribution line patterns 322 may be formed together and integrated with some of the plurality of redistribution vias 324. For example, a redistribution line pattern 322 and a redistribution via 324 contacting the top surface of the redistribution line pattern 322 may be integrated with each other.

According to some embodiments, the plurality of first redistribution vias 324 may have a tapered shape in which the horizontal width thereof decreases upward in the vertical direction. For example, the horizontal width of the plurality of redistribution vias 324 may increase in a direction away from the first semiconductor chip 100.

Some of the plurality of redistribution line patterns 322 arranged on the top surface of the interposer 300 may be referred to as redistribution top surface pads, whereas some other of the plurality of redistribution line patterns 322 arranged on the bottom surface of the interposer 300 may be referred to as redistribution bottom surface pads. A first front surface connection pad 112 may be connected to a redistribution top surface pad, and a package connection terminal 350 may be disposed on a redistribution bottom surface pad. The package connection terminal 350 may serve as an external connection terminal of the semiconductor package 1. The package connection terminal 350 may connect the semiconductor package 1 to the outside. According to some embodiments, the package connection terminal 350 may be a bump or a solder ball.

According to some other embodiments, the interposer 300 may be a silicon interposer. When the interposer 300 is a silicon interposer, the interposer 300 may further include a base layer including silicon and an internal through electrode penetrating through the base layer, and may include, instead of the redistribution bottom surface pad, an interposer bottom surface pad disposed on the bottom surface of the base layer and having the package connection terminal 350 attached thereto.

The first semiconductor chip 100 includes a first substrate 102, a first wiring layer 120, and a plurality of first through electrodes 130. A plurality of first front surface connection pads 112 may be disposed on the bottom surface of the first semiconductor chip 100, and a plurality of first rear surface connection pads 114 may be disposed on the top surface of the first semiconductor chip 100. The second semiconductor chip 200 includes a second substrate 202, a second wiring layer 220, and a plurality of second through electrodes 230. A plurality of second front surface connection pads 212 may be disposed on the bottom surface of the second semiconductor chip 200, and a plurality of second rear surface connection pads 214 may be disposed on the top surface of the second semiconductor chip 200.

In the present disclosure, a front surface and a rear surface refer to a surface located on the side of an active surface and a surface located on the side of an inactive surface sides, respectively, and a top surface and a bottom surface refer to a surface located on the upper side and a surface located on the lower side in the drawings, respectively. The first substrate 102 and the second substrate 202 may each include silicon (Si). Alternatively, the first substrate 102 and the second substrate 202 may each include a semiconductor element like germanium (Ge) or a compound semiconductor like silicon carbide (SiC), gallium arsenide (GaAs), indium arsenide (InAs), and indium phosphide (InP). The first substrate 102 and the second substrate 202 may each have an active surface and an inactive surface opposite to the active surface. The first substrate 102 and the second substrate 202 may each include a plurality of individual devices of various types on the active surface. The individual devices may include various microelectronic devices, e.g., a metal-oxide-semiconductor field effect transistor (MOSFET) such as a complementary metal-insulator-semiconductor transistor (CMOS transistor), a system large scale integration (LSI), an image sensor such as a CMOS imaging sensor (CIS), a micro-electro-mechanical system (MEMS), an active device, a passive device, etc.

The first semiconductor chip 100 and the second semiconductor chip 200 may include a first semiconductor element and a second semiconductor element constituted by the plurality of individual devices, respectively. The first semiconductor element may be disposed on an active surface of the first substrate 102, and the second semiconductor element may be disposed on an active surface of the second substrate 202.

The first semiconductor chip 100 and the second semiconductor chip 200 may each be a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

According to some embodiments, the first semiconductor chip 100 may not include a memory cell. The first semiconductor device included in the first semiconductor chip 100 may include a serial-parallel conversion circuit, a test logic circuit such as a design for test (DFT), a joint test action group (JTAG), and a memory built-in self (MBIST), a signal interface circuit such as a physical layer (PHY). The second semiconductor elements included in the plurality of second semiconductor chips 200 may include memory cells. For example, the first semiconductor chip 100 may be a buffer chip for controlling the plurality of second semiconductor chips 200.

According to some embodiments, the first semiconductor chip 100 may be a buffer chip for controlling a high bandwidth memory (HBM) DRAM, and the plurality of second semiconductor chips 200 may be memory cell chips having HBM DRAM cells controlled by the first semiconductor chip 100. The first semiconductor chip 100 may be referred to as a buffer chip or a master chip, and the second semiconductor chip 200 may be referred to as a memory cell chip or a slave chip. The first semiconductor chip 100 and the plurality of second semiconductor chips 200 stacked on the first semiconductor chip 100 may be collectively referred to as HBM DRAM devices or HBM DRAM chips.

The first wiring layer 120 may be disposed on the active surface of the first substrate 102. The plurality of first front surface connection pads 112 and the plurality of first rear surface connection pads 114 may be disposed on the first wiring layer 120 and on the inactive surface of the first substrate 102, respectively. For example, the plurality of first rear surface connection pads 114 may be disposed on the top surface of the first semiconductor chip 100, and the plurality of first front surface connection pads 112 may be disposed on the bottom surface of the first semiconductor chip 100.

The first wiring layer 120 may include a plurality of first wiring patterns 122, a plurality of first wiring vias 124, and a first inter-wire insulation layer 126. The plurality of first wiring vias 124 may be connected to the top surfaces and/or the bottom surfaces of the plurality of first wiring patterns 122. According to some embodiments, the plurality of first wiring patterns 122 may be spaced apart from one another at different vertical levels, and the plurality of first wiring vias 124 may interconnect the plurality of first wiring patterns 122 disposed at different vertical levels. The plurality of first wiring patterns 122 and the plurality of first wiring vias 124 may electrically interconnect the plurality of first through electrodes 130 and the plurality of first front surface connection pads 112. The first inter-wire insulation layer 126 may be disposed adjacent to and surround the plurality of first wiring patterns 122 and the plurality of first wiring vias 124.

The plurality of first through electrodes 130 may vertically penetrate through at least a portion of the first substrate 102 to electrically interconnect the plurality of first front surface connection pads 112 and the plurality of first rear surface connection pads 114. For example, the plurality of first front surface connection pads 112 and the plurality of first rear surface connection pads 114 may be electrically connected to each other through the plurality of first through electrodes 130, the plurality of first wiring patterns 122, and the plurality of first wiring vias 124.

The second wiring layer 220 may be disposed on the active surface of the second substrate 202. The plurality of second front surface connection pads 212 and the plurality of second rear surface connection pads 214 may be disposed on the second wiring layer 220 and on the inactive surface of the second substrate 202, respectively.

The second wiring layer 220 may include a plurality of second wiring patterns 222, a plurality of second wiring vias 224, and a second inter-wire insulation layer 226. The plurality of second wiring vias 224 may be connected to the top surfaces and/or the bottom surfaces of the plurality of second wiring patterns 222. According to some embodiments, the plurality of second wiring patterns 222 may be spaced apart from one another at different vertical levels, and the plurality of second wiring vias 224 may interconnect the plurality of second wiring patterns 222 disposed at different vertical levels. The plurality of second wiring patterns 222 and the plurality of second wiring vias 224 may electrically interconnect the plurality of second through electrodes 230 and the plurality of second rear surface connection pads 214. The second inter-wire insulation layer 226 may be disposed adjacent to and surround the plurality of second wiring patterns 222 and the plurality of second wiring vias 224.

The plurality of second through electrodes 230 may vertically penetrate through at least a portion of the second substrate 202 to electrically interconnect the plurality of second front surface connection pads 212 and the plurality of second rear surface connection pads 214. For example, the plurality of second front surface connection pads 212 and the plurality of second rear surface connection pads 214 may be electrically connected to each other through the plurality of second through electrodes 230, the plurality of second wiring patterns 222, and the plurality of second wiring vias 224.

The plurality of first wiring patterns 122, the plurality of first wiring vias 124, the plurality of second wiring patterns 222, and the plurality of second wiring vias 224 may include metals such as copper (Cu) or aluminum (Al), tungsten (W), titanium (Ti), tantalum (Ta), molybdenum (Mo), cobalt (Co), nickel (Ni), alloys thereof, or nitrides of these metals. The first inter-wire insulation layer 126 and the first inter-wire insulation layer 126 may each include a high density plasma (HDP) oxide layer, a TEOS oxide layer, a Tonen SilaZene (TOSZ) layer, a spin-on-glass (SOG) layer, an undoped silica glass (USG) layer, or a low-k dielectric layer.

Each of the plurality of first through electrodes 130 and the plurality of second through electrodes 230 may include a conductive plug and a conductive barrier layer surrounding the conductive plug. The conductive plug may include copper (Cu) or tungsten (W). For example, the conductive plug may include Cu, copper tin (CuSn), copper magnesium (CuMg), copper nickel (CuNi), copper zinc (CuZn), copper palladium (CuPd), copper gold (CuAu), copper rhenium (CuRe), copper tungsten (CuW), W, or a W alloy, but is not limited thereto. For example, the conductive plug may include one or more from among Al, Au, Be, Bi, Co, Cu, Hf, In, Mn, Mo, Ni, Pb, Pd, Pt, Rh, Re, Ru, Ta, Te, Ti, W, Zn, and Zr and may include a stacked structure of one or more thereof. The conductive barrier film may include at least one material selected from among W, tungsten nitride (WN), tungsten carbide (WC), Ti, titanium nitride (TiN), Ta, tantalum nitride (TaN), Ru, Co, Mn, Ni, and nickel boride (NiB) and may include a single layer or multiple layers.

A plurality of chip connection terminals 250 may be disposed on the plurality of second front surface connection pads 212, respectively. The plurality of chip connection terminals 250 may each be disposed between a first rear surface connection pad 114 and a second front surface connection pad 212 facing each other or between a second rear surface connection pad 214 and the second front surface connection pad 212 facing each other. In detail, the plurality of chip connection terminals 250 may be disposed between the plurality of first rear surface connection pads 114 and the plurality of second front surface connection pads 212 disposed on the lowermost second semiconductor chip 200 from among the plurality of second semiconductor chips 200 and between the plurality of second front surface connection pads 212 disposed on the other second semiconductor chips 200 from among the plurality of second semiconductor chips 200 and the plurality of second rear surface connection pads 214 disposed on another second semiconductor chip 200 therebelow to electrically interconnect the first semiconductor chip 100 and the plurality of second semiconductor chips 200.

The second front surface connection pad 212 to which a chip connection terminal 250 is attached may be referred to as a front surface connection pad, the first rear surface connection pad 114 and the second rear surface connection pad 214 to which the chip connection terminals 250 are attached may be referred to as rear surface connection pads, and the first front surface connection pad 112 may be referred to as an interposer connection pad.

According to some embodiments, an uppermost second semiconductor chip 200T disposed farthest from the first semiconductor chip 100 from among the plurality of second semiconductor chips 200 may not include the second rear surface connection pads 214 and second through electrodes 230. According to some embodiments, from among the second semiconductor chips 200, the uppermost second semiconductor chip 200T that is the farthest from the first semiconductor chip 100 may have a thickness greater than that of each of the other second semiconductor chips 200.

The insulating adhesive layer 260 is disposed on the inactive surfaces of the second substrate 202 of the second semiconductor chips 200 other than the uppermost second semiconductor chip 200T from among the plurality of second semiconductor chips 200 and the inactive surface of the first substrate 102 and may attach each of the plurality of second semiconductor chips 200 to a structure therebelow, e.g., the first semiconductor chip 100 or another second semiconductor chip 200 therebelow from among the plurality of second semiconductor chips 200. The insulating adhesive layer 260 may surround the chip connection terminals 250 and fill gaps between the first semiconductor chip 100 and the plurality of second semiconductor chips 200.

According to embodiments, the insulating adhesive layer 260 may include a non-conductive film (NCF) including heterogeneous materials. The insulating adhesive layer 260 may be fabricated in the form of a laminatable film containing heterogeneous materials and may be disposed on the top surfaces of the first semiconductor chip 100 and the second semiconductor chip 200.

The molding layer 290 may be disposed on the first semiconductor chip 100 to surround the plurality of second semiconductor chips 200 and the plurality of insulating adhesive layers 260. The molding layer 290 may include, for example, an epoxy molding compound (EMC). According to some embodiments, the molding layer 290 may cover side surfaces of the plurality of second semiconductor chips 200, side surfaces of the plurality of insulating adhesive layers 260, and the top surface of the uppermost second semiconductor chip 200T from among the plurality of second semiconductor chips 200 together.

According to embodiments, sidewalls 100S of the first semiconductor chip 100 may protrude outward with respect to sidewalls 290S of the molding layer 290 in a horizontal direction, and thus a stepped portion may be formed at the boundary between the sidewalls 100S of the first semiconductor chip 100 and the sidewalls 290S of the molding layer 290. For example, the first semiconductor chip 100 may have a first width w21 in a horizontal direction (e.g., the first horizontal direction X), and the molding layer 290 may have a second width w22 smaller than the first width w21 in the horizontal direction (e.g., the first horizontal direction X).

The marking layer 295 may be disposed on edges at a peripheral region of a top surface 100U of the first semiconductor chip 100 and may surround the molding layer 290 when viewed in a plan view. For example, the marking layer 295 may be disposed on the stepped portion formed at the boundary between the sidewalls 100S of the first semiconductor chip 100 and the sidewalls 290S of the molding layer 290. As shown in FIG. 3, inner sidewalls 295SI of the marking layer 295 (e.g., sidewalls facing the plurality of second semiconductor chips 200) may contact the lower portion of the sidewalls 290S of the molding layer 290, and outer sidewalls 295SO of the marking layer 295 may be aligned with and coplanar with the sidewalls 100S of the first semiconductor chip 100. According to some embodiments, unlike as shown in FIG. 3, the inner sidewalls 295SI of the marking layer 295 may not directly contact the sidewalls 290S of the molding layer 290 and a gap having a small and uniform width may be formed between the inner sidewalls 295SI of the marking layer 295 and the sidewalls 290S of the molding layer 290.

According to embodiments, the marking layer 295 may include a hydrophobic material, for example, fluorine (F). For example, the marking layer 295 may include a fluorocarbon layer. The marking layer 295 may be formed through a chemical vapor deposition (CVD) process, a physical vapor deposition (PVD) process, a spin coating process, etc. According to embodiments, the marking layer 295 may be formed through a CVD process using a precursor including octafluorocyclobutane (C₄F₈), tetrafluoromethane (CF₄), or trifluoromethane (CHF₃).

According to embodiments, surfaces of the marking layer 295 may have hydrophobic characteristics, and thus, in the process of forming the molding layer 290, due to the locally relatively low surface energy of the surface of the marking layer 295, the marking layer 295 may function as a self-aligned cutting line or an anti-adhesive layer preventing the molding layer 290 from being disposed on the top surface of the marking layer 295.

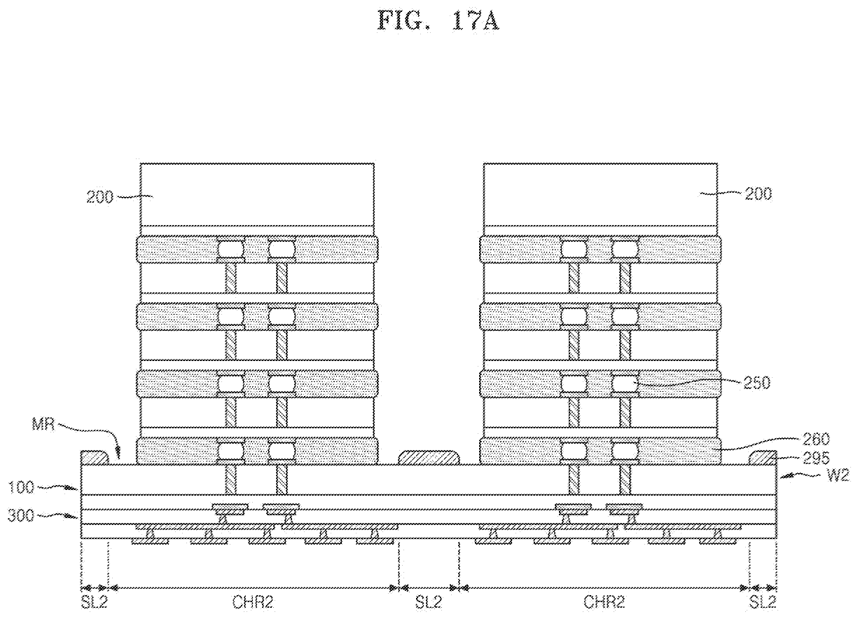

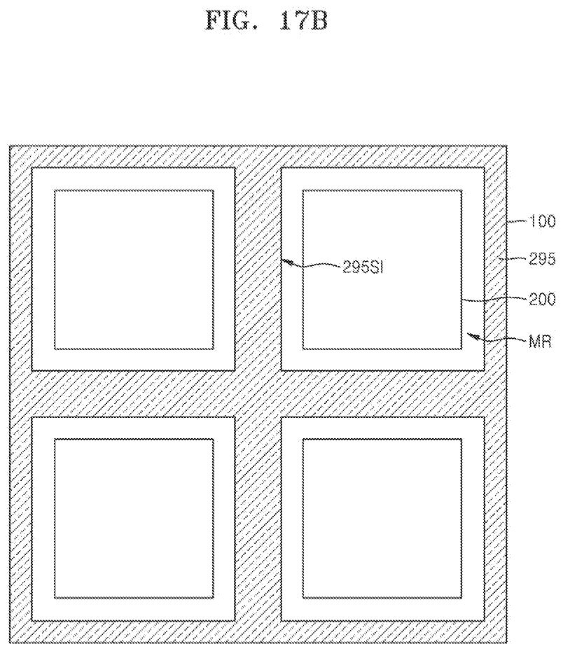

In the process of manufacturing the semiconductor package 1 according to embodiments, the marking layer 295 may be formed first on a portion of the top surface 100U of the first semiconductor chip 100 corresponding to a scribe lane region SL2 (refer to FIG. 17A. The marking layer 295 may define a molding region MR (refer to FIG. 17A) surrounding the plurality of second semiconductor chips 200 when viewed in a plan view. The molding layer 290 may then be formed in the molding region MR on the top surface of the first semiconductor chip 100. At this time, due to the hydrophobic characteristics of the surface of the marking layer 295, the molding layer 290 may not be coated or dispensed onto the top surface of the marking layer 295, and the molding layer 290 may be confined into the molding region MR defined by the inner sidewalls 295SI of the marking layer 295. For example, the inner sidewalls 295SI of the marking layer 295 may correspond to surfaces formed on the top surface 100U of the first semiconductor chip 100 and serving as a self-aligned cutting line. When the sidewalls of the first semiconductor chip 100 are formed by cutting the first semiconductor chip 100 in the process of individualizing the semiconductor package 1, the outer walls 295SO of the marking layer 295 may be cut together, and thus the outer sidewalls 295SO of the marking layer 295 may be aligned with and coplanar with the sidewalls of the first semiconductor chip 100.

In embodiments, the marking layer 295 may have a first width w11 in a horizontal direction (e.g., the first horizontal direction X), and the first width w11 may be from about 10 micrometers to about 500 micrometers. The marking layer 295 may have a first thickness t11 in the vertical direction Z, and the first thickness t11 may be from about 10 angstroms to about 5000 angstroms.

According to an embodiment, after a plurality of second semiconductor chips are disposed on a wafer including a first semiconductor chip and a molding layer surrounding the plurality of second semiconductor chips is formed, the molding layer and the wafer may be cut together, thereby individualizing the same into a plurality of semiconductor packages. In this case, the sidewalls of the first semiconductor chip and the sidewalls of the molding layer are formed to be aligned with and coplanar with each other. Furthermore, not only a relatively long time is elapsed for a blade to cut the molding layer having a relatively large thickness, but also the blade is contaminated or worn out by an organic material. Therefore, the cost of manufacturing a semiconductor package may increase.

However, according to the embodiments described with reference to FIGS. 1 to 3, the marking layer 295 may be formed on the scribe lane region SL2 on a wafer including the first semiconductor chip 100 to define the molding region MR. and then the molding layer 290 may be dispensed into the molding region MR. Due to the hydrophobic surface characteristics of the marking layer 295, the molding layer 290 may not be disposed on the top surface of the marking layer 295, and thus the inner sidewalls 295SI of the marking layer 295 and the sidewalls 290S of the molding layer 290 may contact each other. Also, the molding layer 290 may be formed to have a relatively small width, that is, the second width w22. Therefore, in the cutting process, only a wafer and a portion of the marking layer 295 thereon may be cut without the need of cutting the molding layer 290. Therefore, the time elapsed for the cutting process may be reduced, and contamination and wear-off of a blade may be prevented. Therefore, the cost of manufacturing the semiconductor package 1 may be reduced.

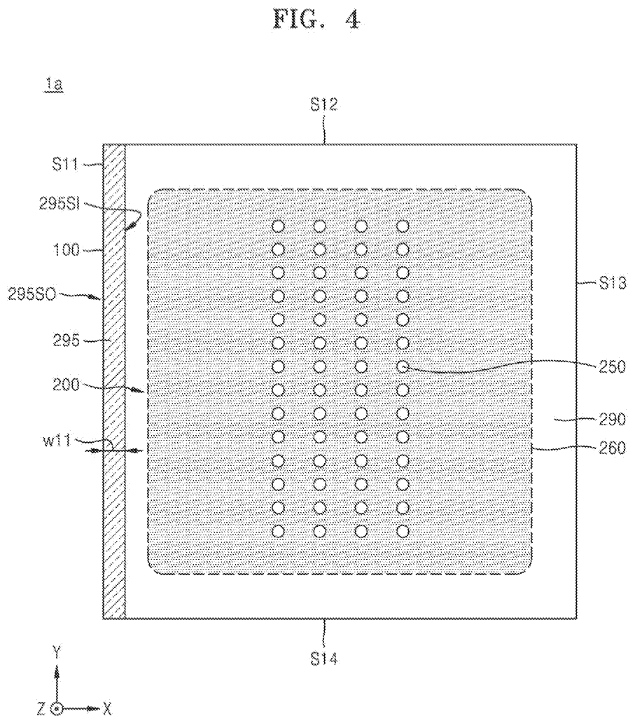

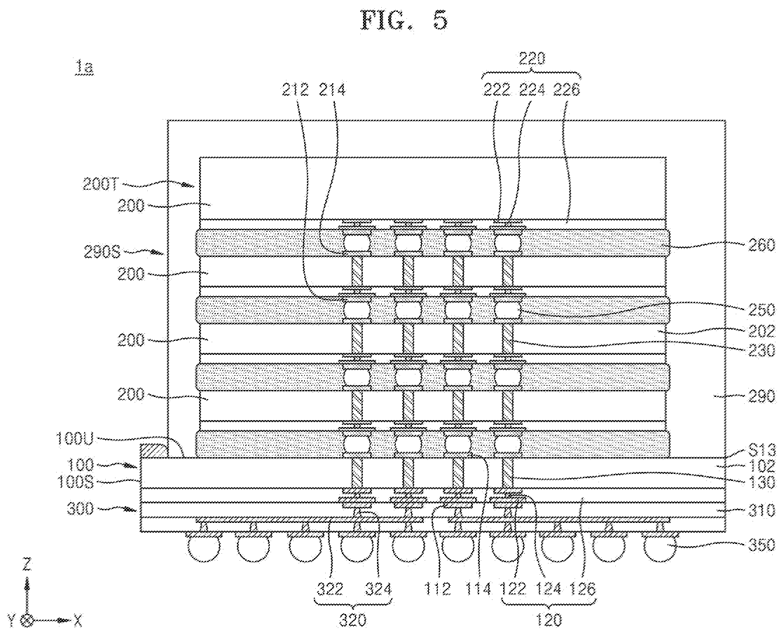

FIG. 4 is a plan view of a semiconductor package 1a according to embodiments, and FIG. 5 is a cross-sectional view of the semiconductor package 1a.

Referring to FIGS. 4 and 5, the first semiconductor chip 100 may include a first side surface S11, a second side surface S12, a third side surface S13, and a fourth side surface S14, and the marking layer 295 may be disposed on at least one side of the first semiconductor chip 100 to be adjacent to a first side surface S11, for example. For example, the marking layer 295 may be formed on the top surface 100U of the first semiconductor chip 100 to surround the molding layer 290 when viewed in a plan view to contact four sidewalls 290S of the molding layer 290, and, in a subsequent process of individualizing into semiconductor packages, portions of the marking layer 295 disposed adjacent to second to fourth side surfaces S12, S13, and S14 of the first semiconductor chip 100 may be cut and removed, and only the portion of the marking layer 295 disposed adjacent to the first side surface S11 of the first semiconductor chip 100 may remain.

For example, as shown in FIG. 5, a sidewall 290S of the molding layer 290 disposed adjacent to the first side surface S11 of the first semiconductor chip 100 may be recessed inwardly with respect to the first side surface S11 of the first semiconductor chip 100, and the sidewall 290S of the molding layer 290 disposed adjacent to a third side surface S13 of the first semiconductor chip 100 may be aligned and disposed on the same plane with the third side surface S13 of the first semiconductor chip 100.

According to embodiments, the bottom surface of a portion of the molding layer 290 (e.g., the bottom surface of a portion of the molding layer 290 contacting the top surface 100U of the first semiconductor chip 100) disposed adjacent to the third side surface S13 of the first semiconductor chip 100 may have a greater width in the first horizontal direction X than the bottom surface of a portion of the molding layer 290 disposed adjacent to the first side surface S11 of the first semiconductor chip 100. According to other embodiments, the bottom surface of a portion of the molding layer 290 (e.g., the bottom surface of a portion of the molding layer 290 contacting the top surface 100U of the first semiconductor chip 100) disposed adjacent to the third side surface S13 of the first semiconductor chip 100 may have the same width in the first horizontal direction X than the bottom surface of a portion of the molding layer 290 disposed adjacent to the first side surface S11 of the first semiconductor chip 100.

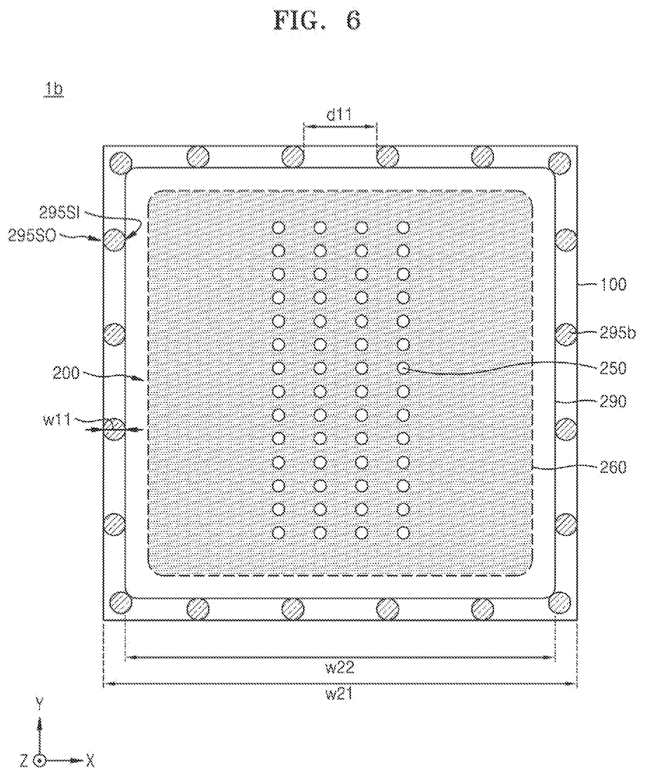

FIG. 6 is a plan view of a semiconductor package 1b according to embodiments.

Referring to FIG. 6, a marking layer 295b may include a plurality of marking layers spaced apart from each other on edges at a peripheral region of the first semiconductor chip 100 and the marking layer 295b may have a shape of a plurality of island patterns. For example, the marking layer 295b may have a circular horizontal cross-sectional shape. The marking layer 295b may have the first width w11. For example, the width of the horizontal cross-section of the marking layer 295b in a direction perpendicular to the sidewall 290S of the molding layer 290 may be the first width w11. The width of the horizontal cross-section of the marking layer 295b in a direction parallel to the sidewall 290S of the molding layer 290 may be identical to the first width w11. According to another embodiment, any one of the width of the horizontal cross-section of the marking layer 295b in the direction perpendicular to the sidewalls 290S of the molding layer 290 and the width of the horizontal cross-section of the marking layer 295b in the direction parallel to the sidewalls 290S of the molding layer 290 may be greater than the other one. In this case, the horizontal cross-section of the molding layer 290 may have an elliptical shape. Two adjacent marking layers 295b may be spaced apart from each other by a first distance d11. The first width w11 may be from about 10 micrometers to about 500 micrometers, and the first distance d11 may be from about 10 micrometers to about 500 micrometers.

At least one of the width of the horizontal cross-section of the marking layer 295b in the direction perpendicular to the sidewalls 290S of the molding layer 290 and the width of the horizontal cross-section of the marking layer 295b in the direction parallel to the sidewalls 290S of the molding layer 290 may be greater than the first distance d11 between the marking layers 295b. According to another embodiment, at least one of the width of the horizontal cross-section of the marking layer 295b in the direction perpendicular to the sidewalls 290S of the molding layer 290 and the width of the horizontal cross-section of the marking layer 295b in the direction parallel to the sidewalls 290S of the molding layer 290 may be smaller than the first distance d11 between the marking layers 295b. According to another embodiment, at least one of the width of the horizontal cross-section of the marking layer 295b in the direction perpendicular to the sidewalls 290S of the molding layer 290 and the width of the horizontal cross-section of the marking layer 295b in the direction parallel to the sidewalls 290S of the molding layer 290 may be identical or similar to the first distance d11 between the marking layers 295b. This may be similarly applied to other embodiments below.

The marking layer 295b may include the inner sidewalls 295SI contacting the sidewalls 290S of the molding layer 290, and a material constituting the molding layer 290 having a relatively high viscosity may be formed in the molding region MR defined by connection lines of the sidewalls 290S between the marking layers 295b during a process of dispensing the molding layer 290. Therefore, the sidewalls 290S of the molding layer 290 may be disposed to be recessed inwardly with respect to the sidewalls 100S of the first semiconductor chip 100 in a horizontal direction.

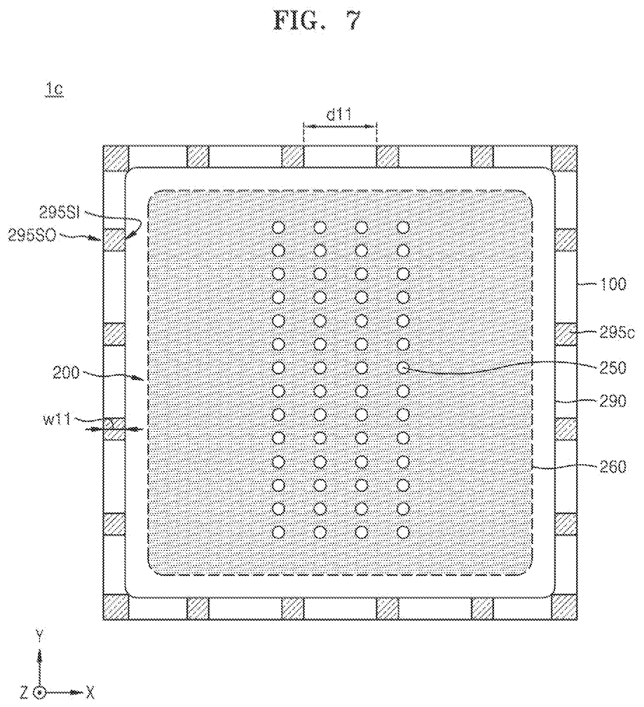

FIG. 7 is a plan view of a semiconductor package 1c according to embodiments.

Referring to FIG. 7, a marking layer 295c may have a shape of a plurality of island patterns, and, for example, the marking layer 295c may have a rectangular horizontal cross-sectional shape. The marking layer 295c may have the first width w11, and two adjacent marking layers 295c may be spaced apart from each other by the first distance d11. The first width w11 may be from about 10 micrometers to about 500 micrometers, and the first distance d11 may be from about 10 micrometers to about 500 micrometers. According to an embodiment, the width of the horizontal cross-section of the marking layer 295b in a direction parallel to the sidewall 290S of the molding layer 290 may be identical to the first width w11. According to another embodiment, any one of the width of the horizontal cross-section of the marking layer 295b in the direction perpendicular to the sidewalls 290S of the molding layer 290 and the width of the horizontal cross-section of the marking layer 295b in the direction parallel to the sidewalls 290S of the molding layer 290 may be greater than the other one. In this case, the horizontal cross-section of the molding layer 290 may have a rectangular shape.

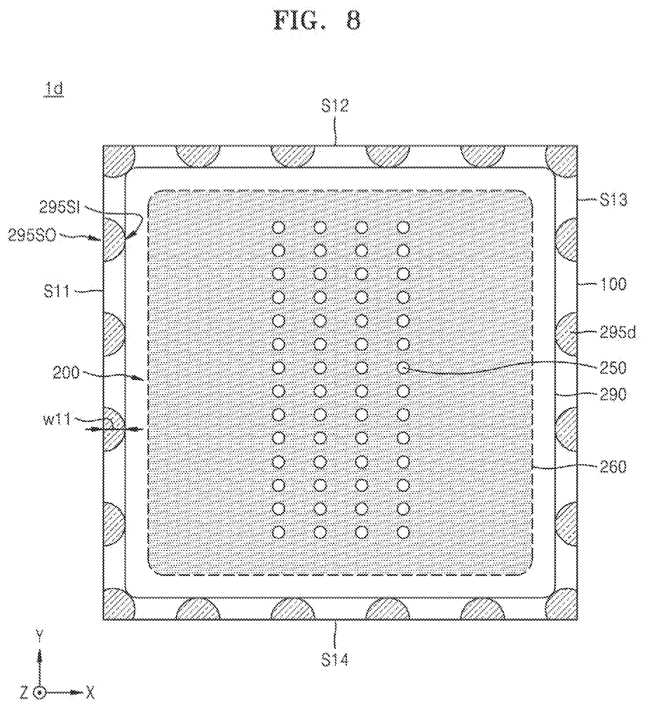

FIG. 8 is a plan view of a semiconductor package 1d according to embodiments.

Referring to FIG. 8, a marking layer 295d may have a shape of a plurality of island patterns. For example, the marking layer 295d may have a semicircular horizontal cross-sectional shape. The inner sidewalls 295SI of the marking layer 295d may be disposed to contact the molding layer 290, and the outer sidewalls 295SO opposite to the inner sidewalls 295SI of the marking layer 295d may be disposed to be aligned with and coplanar with the first to fourth side surfaces S11, S12, S13, and S14 of the first semiconductor chip 100.

According to embodiments, the marking layer 295d having a circular cross-section may be first formed on a wafer including the first semiconductor chip 100, the molding layer 290 may be formed thereafter, and the semiconductor package 1d may be cut along the center portion of the marking layer 295d in an individualization process, and thus the marking layer 295d having a semicircular cross-sectional shape may remain in an edge region of the first semiconductor chip 100.

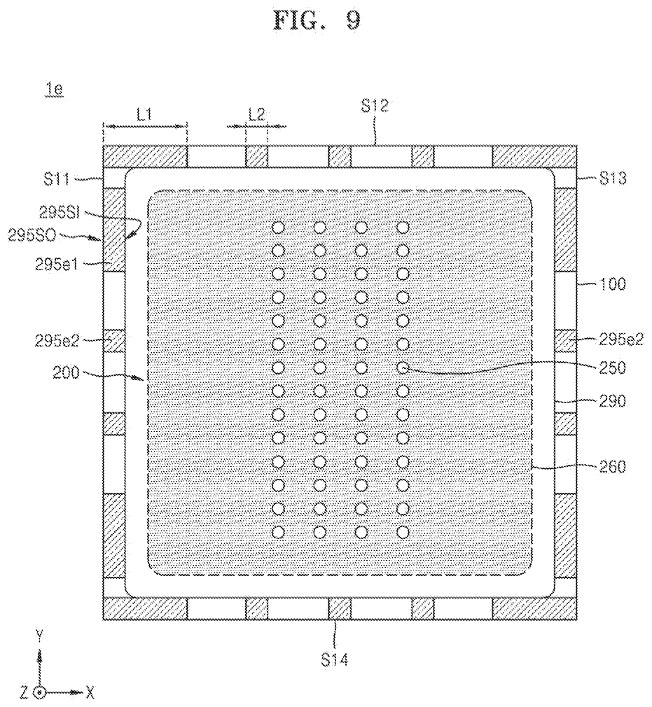

FIG. 9 is a plan view of a semiconductor package 1e according to embodiments.

Referring to FIG. 9, first marking layers 295ei having a first length L1 and second marking layers 295e2 having a second length L2 may be disposed on portions of the top surface 100U of the first semiconductor chip 100 adjacent to the first to fourth side surfaces S11, S12, S13, and S14 of the first semiconductor chip 100. According to some embodiments, the first marking layers 295ei having a first length L1 may be disposed adjacent to four corners of the first semiconductor chip 100, and the second marking layers 295e2 having a second length L2 smaller than the first length L1 may be disposed between the first marking layers 295ei of the first semiconductor chip 100.

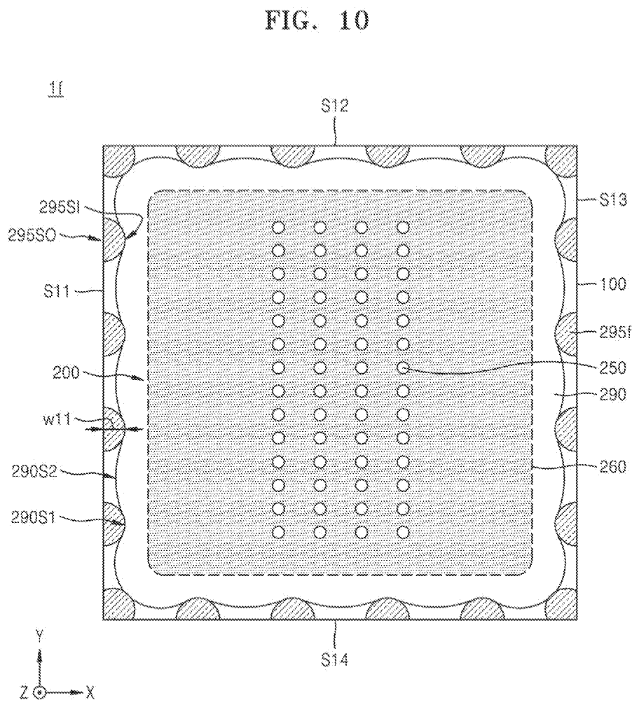

FIG. 10 is a plan view of a semiconductor package 1f according to embodiments.

Referring to FIG. 10, a marking layer 295f may have an island pattern shape and may have, for example, a semicircular horizontal cross-sectional shape similar to that of the marking layer 295d described with reference to FIG. 8. The molding layer 290 may include a concave sidewall 290S1 contacting the marking layer 295f and a protruding sidewall 290S2 convexly protruding outward toward a space between two adjacent marking layers 295f. For example, when the marking layers 295f are disposed in the form of island patterns, as a molding material having a relatively low viscosity is dispensed onto the top surface of the first semiconductor chip 100, e.g., into the molding region MR, the molding layer 290 may be formed to have the concave sidewall 290S1 contacting the inner sidewalls 295SI of the marking layers 295f without flowing onto the marking layers 295f due to the hydrophobic characteristics of the surfaces of the marking layers 295f, and the molding material may form the protruding sidewall 290S2 convexly protruding outwardly by flowing toward a space between two adjacent marking layers 295f.

According to other embodiments, the marking layer 295f may have a shape similar to those of marking layers 295b, 295c, 295ei, and 295e2 described above with reference to FIGS. 6, 7, and 9. For example, when the marking layer 295f has a shape similar to those of the marking layers 295c, 295ei, and 295e2 described above with reference to FIGS. 7 and 9, sidewalls of the molding layer 290 contacting the inner sidewalls 295SI of the marking layer 295f may have a flat shape instead of concave sidewalls 290S1.

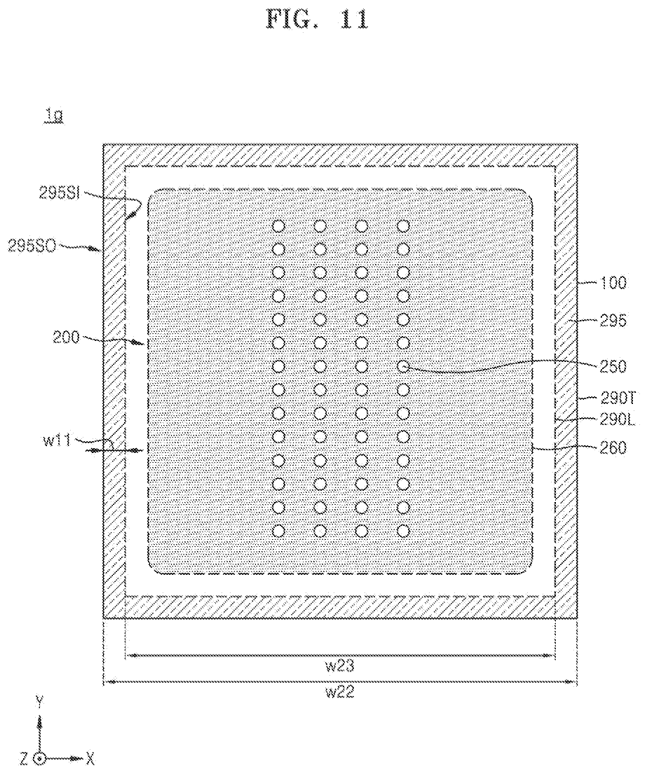

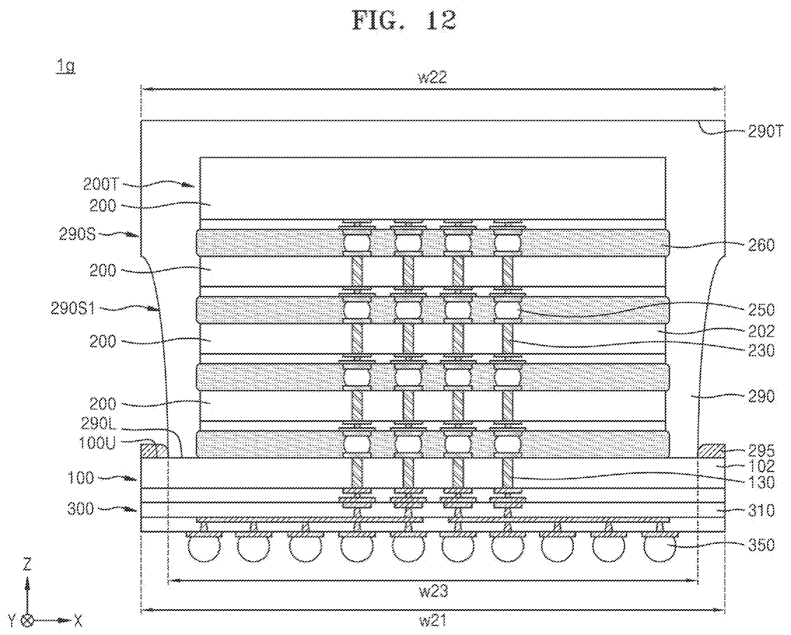

FIG. 11 is a plan view of a semiconductor package 1g according to embodiments. FIG. 12 is a cross-sectional view of the semiconductor package 1g.

Referring to FIGS. 11 and 12, the first semiconductor chip 100 may have the first width w21, an upper portion 290T of the molding layer 290 may have the second width w22, and the second width w22 may be substantially the same as the first width w21. A bottom portion 290L of the molding layer 290 may have a third width w23 smaller than the second width w22. The bottom portion 290L of the molding layer 290 may have the concave sidewalls 290S1 defined by the inner sidewalls 295SI of the marking layer 295, and the concave sidewalls 290S1 may be recessed inwardly with respect to sidewall 290S of the upper portion 290T of the molding layer 290.

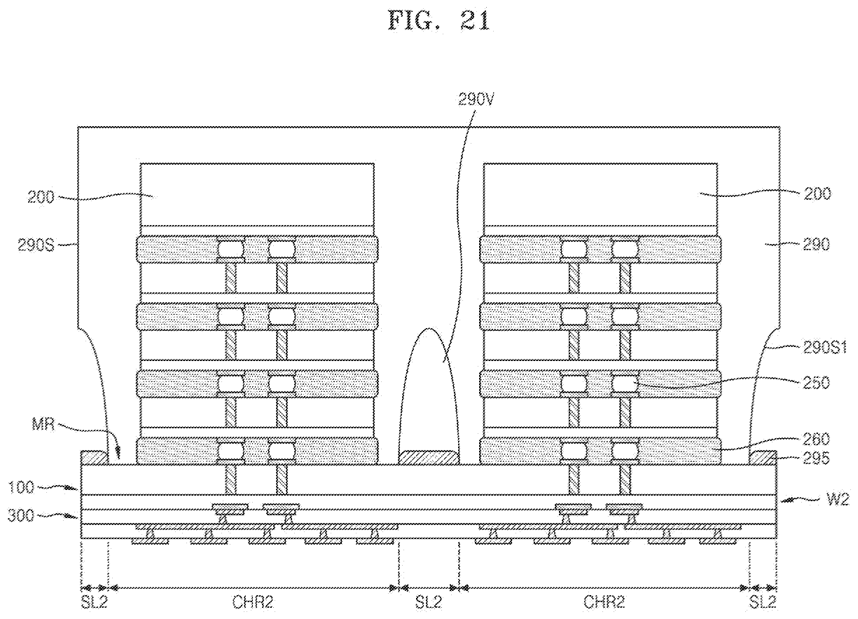

In the manufacturing process according to embodiments, when the marking layer 295 is disposed on the top surface 100U of the first semiconductor chip 100, a molding material is dispensed onto the top surface 100U of the first semiconductor chip 100, the molding layer 290 may be formed to have the concave sidewalls 290S1 contacting the inner sidewalls 295SI of the marking layer 295 without flowing onto the marking layer 295 due to the hydrophobic characteristics of the surface of the marking layer 295, and, as the molding material may flow in lateral directions around the uppermost second semiconductor chip 200T located relatively far from the top surface 100U of the first semiconductor chip 100, the molding material may be connected to the molding material surrounding another uppermost second semiconductor chip 200T. Therefore, voids 290V (refer to FIG. 21) may be formed at a vertical position close to the top surface 100U of the first semiconductor chip 100, and the concave sidewalls 290S1 may formed the interface between the molding layer 290 and the voids 290V. The sidewalls 290S of the molding layer 290 may be formed as a connection portion of the molding layer 290 disposed at a vertical position far from the top surface 100U of the first semiconductor chip 100 is cut.

According to embodiments, as the upper portion 290T of the molding layer 290 and a wafer are cut in the process of individualizing the semiconductor package 1g, the second width w22 of the upper portion 290T of the molding layer 290 may become substantially the same as the first width w11 of the first semiconductor chip 100. Therefore, as the voids 290V are formed on the top surface of the first semiconductor chip 100, contamination, damage, or wear-off of a blade may be reduced during the individualization process.

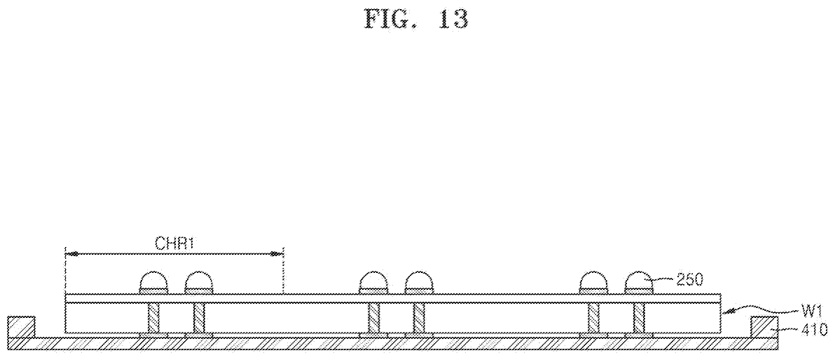

FIGS. 13 to 20 are schematic diagrams showing a method of manufacturing a semiconductor package according to embodiments. In detail, FIGS. 13 to 16, 17a, and 18 to 20 are cross-sectional views according to a process sequence, and FIG. 17B is a plan view corresponding to FIG. 17A.

Referring to FIG. 13, a wafer W1 may be disposed on a support substrate 410. The wafer W1 may include a plurality of chip regions CHR1, and the plurality of chip regions CHR1 may include the plurality of second semiconductor chips 200 described above with reference to FIGS. 1 to 13. The plurality of chip connection terminals 250 may be disposed on the top surface of the wafer W1.

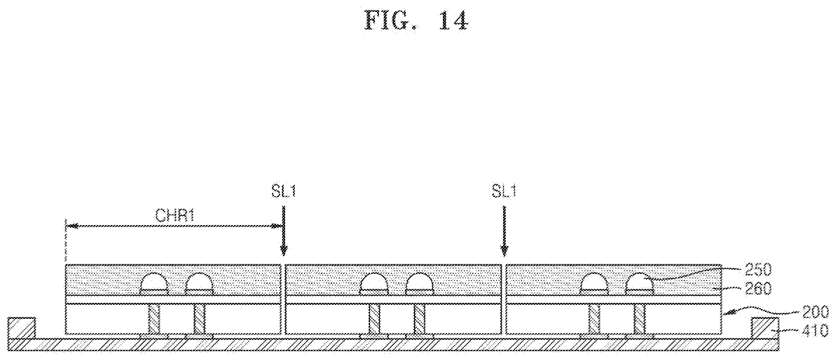

Referring to FIG. 14, the insulating adhesive layer 260 may be attached onto the top surface of the wafer W1, such that the insulating adhesive layer 260 contacts the top surface of the wafer W1 (e.g., the insulating adhesive layer 260 covers the top surfaces of the chip connection terminals 250).

Thereafter, the wafer W1 may be individualized into the plurality of second semiconductor chips 200 by cutting the wafer W1 along a scribe lane SL1. The insulating adhesive layer 260 may be disposed on the top surface of each of the second semiconductor chips 200.

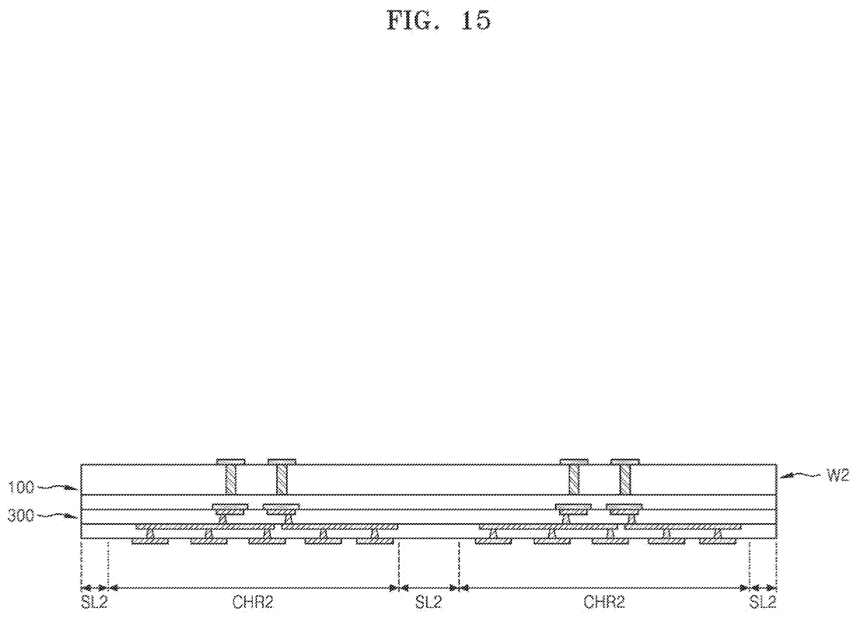

Referring to FIG. 15, a second wafer W2 disposed on the interposer 300 is prepared. The second wafer W2 may include the first semiconductor chip 100. The second wafer W2 may include a plurality of chip regions CHR2 and the scribe lane region SL2.

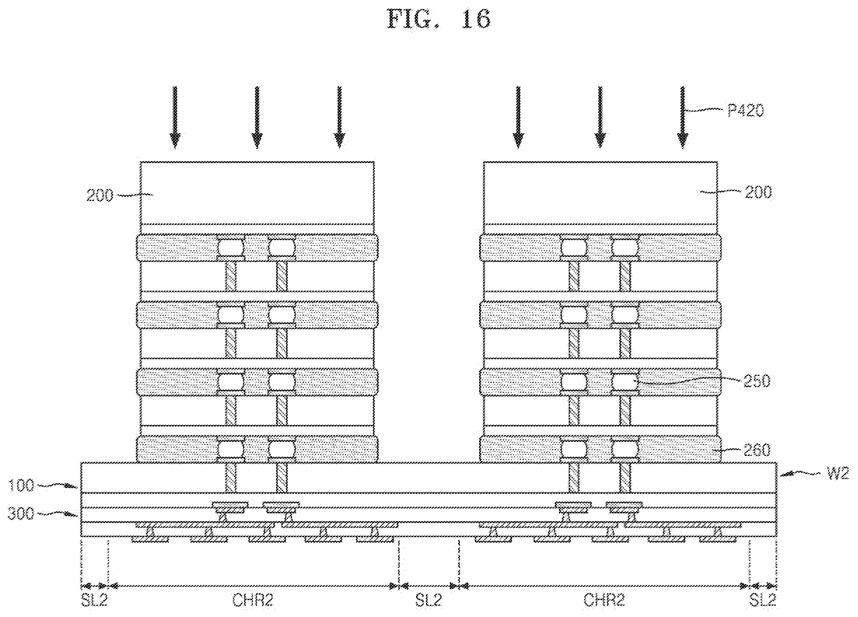

Referring to FIG. 16, the plurality of second semiconductor chips 200 may be sequentially stacked on the first semiconductor chip 100. The insulating adhesive layer 260 may be disposed on the top surface of each of the plurality of second semiconductor chips 200 to surround the chip connection terminals 250.

According to embodiments, in the process of stacking the plurality of second semiconductor chips 200, the chip connection terminals 250 may be firmly disposed on pads disposed above and below the chip connection terminals 250 (e.g., the second front surface connection pads 212 and the second rear surface connection pads 214, refer to FIG. 1). For example, a thermal compression process P420 of applying certain heat and pressure to the plurality of second semiconductor chips 200, the chip connection terminals 250, and the insulating adhesive layer 260 therebetween may be performed.

Referring to FIGS. 17A and 17B, the marking layer 295 may be formed on the scribe lane region SL2 of the second wafer W2. According to embodiments, the marking layer 295 may be formed to be spaced apart from the plurality of second semiconductor chips 200 in a horizontal direction, and the inner sidewalls 295SI of the marking layer 295 may be formed to surround the plurality of second semiconductor chips 200 when viewed in a plan view. For example, the molding region MR may be defined by the inner sidewalls 295SI of the marking layer 295.

According to embodiments, the marking layer 295 may include a hydrophobic material, for example, fluorine (F). For example, the marking layer 295 may include a fluorocarbon layer. The marking layer 295 may be formed through a chemical vapor deposition (CVD) process, a physical vapor deposition (PVD) process, an atomic layer deposition (ALD) process, a spin coating process, etc. According to embodiments, the marking layer 295 may be formed through a CVD process using a precursor including C₄F₈, CF₄, or CHF₃.

According to embodiments, a mask pattern surrounding the plurality of second semiconductor chips 200 may be formed on the second wafer W2, and the mask pattern may not be disposed on the top surface of a portion of the second wafer W2 in the scribe lane region SL2. The marking layer 295 may be formed on the top surface of the portion of the second wafer W2 in the scribe lane region SL2 not covered by the mask pattern through a CVD process, a PVD process, an ALD process, a spin coating process, etc.

According to some embodiments, a surface of the marking layer 295 may have hydrophobic characteristics. An additional surface treatment to enhance hydrophobic surface characteristics such as fluorine plasma treatment may be further performed on the surface of the marking layer 295.

Although FIG. 17B shows an example in which the marking layer 295 is formed to have a grid-like shape or a net-like shape surrounding the plurality of second semiconductor chips 200 when viewed in a plan view, embodiments are not limited thereto, and according to other embodiments, any one of marking layers 295b, 295c, 295d, 295e1, 295e2, and 295f having the horizontal cross-sectional shapes described above with reference to FIGS. 4 to 10 may be formed.

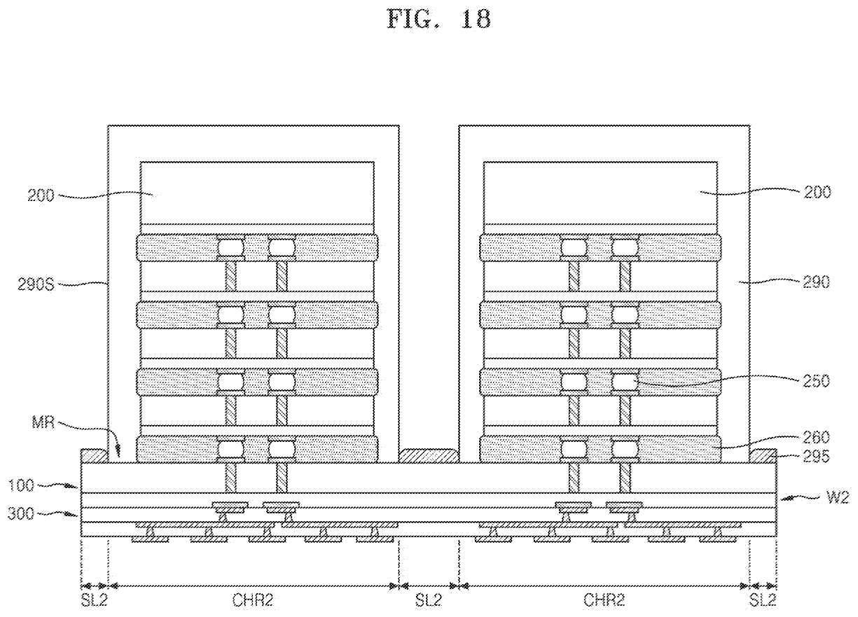

Referring to FIG. 18, the molding layer 290 covering side surfaces of the plurality of second semiconductor chips 200 may be formed on the second wafer W2. For example, a molding material may be supplied onto the second wafer W2 by a dispenser or the like to surround the plurality of second semiconductor chips 200, and, as the molding material is cured, the molding layer 290 may be formed in the molding region MR.

According to embodiments, since a surface of the marking layer 295 has hydrophobic characteristics, the molding layer 290 may not be formed on the surface of the marking layer 295 and may be formed to have the sidewalls 290S defined by the inner sidewalls 295SI of the marking layer 295 and a height sufficient to surround the plurality of second semiconductor chips 200. Only the marking layer 295 may be disposed on the top surface of the second wafer W2 on the scribe lane region SL2, and the molding layer 290 may not be disposed on the scribe lane region SL2. For example, the marking layer 295 may serve as a self-aligned cutting line due to the hydrophobic surface characteristics thereof.

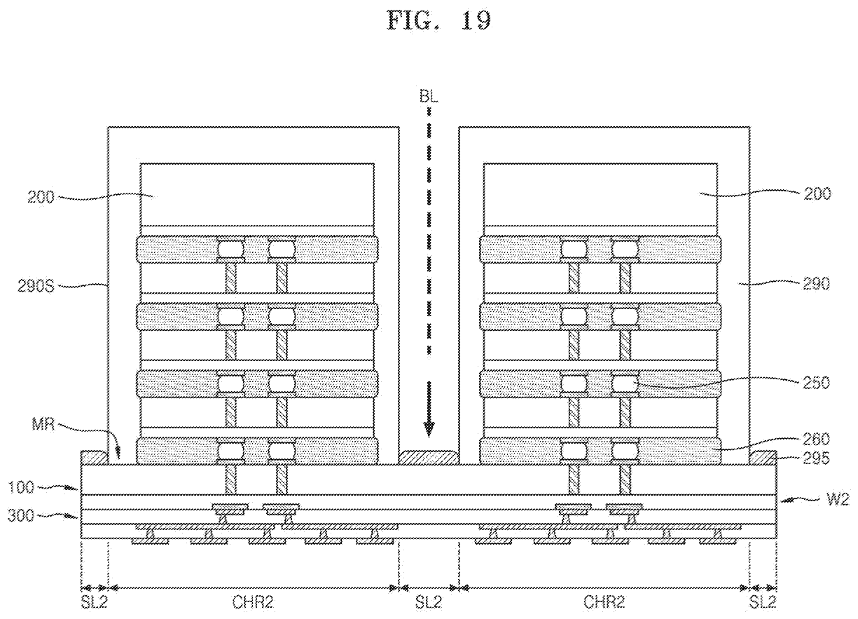

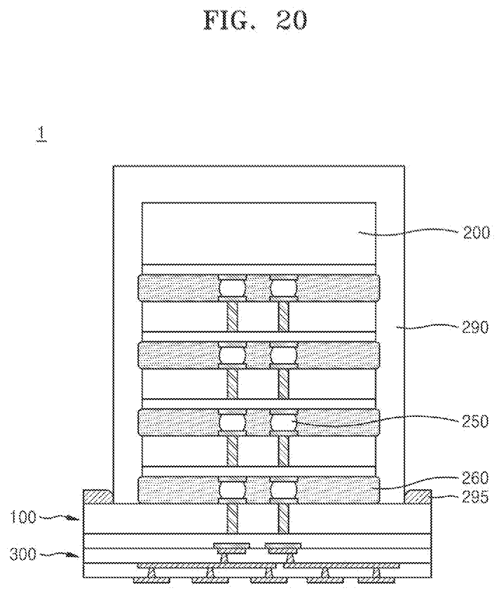

Referring to FIGS. 19 and 20, the semiconductor package 1 may be formed by cutting the second wafer W2 on the scribe lane region SL2 by using a blade BL.

According to embodiments, the marking layer 295 may be formed on the scribe lane region SL2 of the second wafer W2 including the first semiconductor chip 100 to define the molding region MR, and the molding layer 290 may be formed thereafter by dispensing a molding material in the molding region MR. Due to the hydrophobic characteristics of the surface of the marking layer 295, the molding layer 290 may not be disposed on the top surface of the marking layer 295, and thus the inner sidewalls 295SI of the marking layer 295 and the sidewalls 290S of the molding layer 290 may be formed to contact each other. Therefore, in the cutting process, only a wafer and a portion of the marking layer 295 thereon may be cut without the need of cutting the molding layer 290. Therefore, the time elapsed for the cutting process may be reduced, and contamination and wear-off of a blade may be reduced. Therefore, the cost of manufacturing the semiconductor package 1 may be reduced.

FIGS. 21 to 23 are cross-sectional views showing a method of manufacturing a semiconductor package according to embodiments.

First, the marking layer 295 may be formed on the second wafer W2 by performing the processes described above with reference to FIGS. 13 to 17B.

Referring to FIG. 21, the molding layer 290 covering side surfaces of the plurality of second semiconductor chips 200 may be formed on the second wafer W2. For example, a molding material may be supplied onto the second wafer W2 by a dispenser or the like to surround the plurality of second semiconductor chips 200, and, as the molding material is cured, the molding layer 290 may be formed in the molding region MR.

When the marking layer 295 is disposed on the top surface 100U of the first semiconductor chip 100, as a molding material may be dispensed onto the top surface 100U of the first semiconductor chip 100, the molding layer 290 may be formed to have the concave sidewall 290S1 contacting the inner sidewalls 295SI of the marking layer 295 without flowing onto the marking layer 295 due to the hydrophobic characteristics of a surface of the marking layer 295, and, as the molding material may flow in lateral directions around the uppermost second semiconductor chip 200T located relatively far from the top surface 100U of the first semiconductor chip 100, the molding material may be connected to the molding material surrounding another uppermost second semiconductor chip 200T which is disposed adjacent thereto. Therefore, the voids 290V may be formed at a vertical position close to the top surface 100U of the first semiconductor chip 100, and the concave sidewalls 290S1 may formed the interface between the molding layer 290 and the voids 290V. A portion of the molding layer 290 disposed at a vertical position far from the top surface 100U of the first semiconductor chip 100 may fill the space between adjacent second semiconductor chips 200.

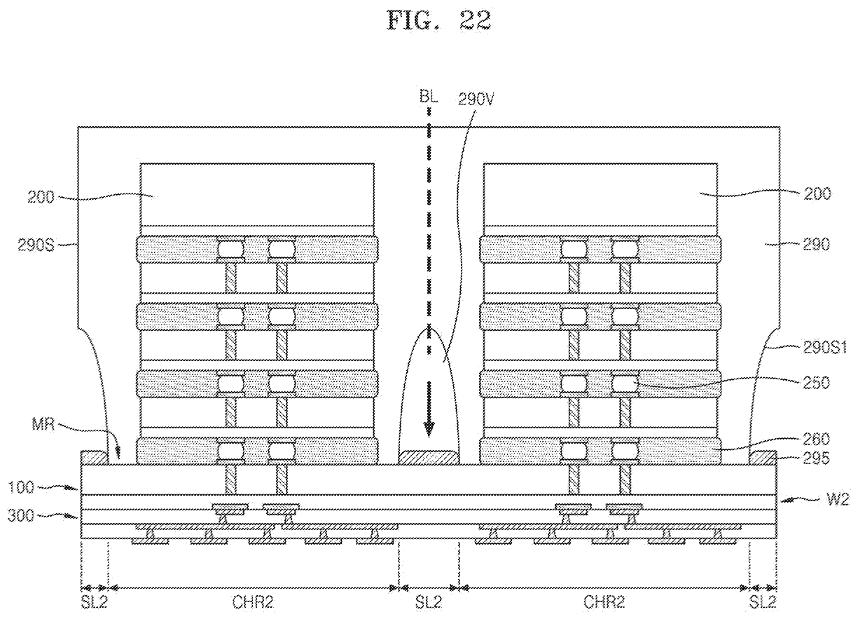

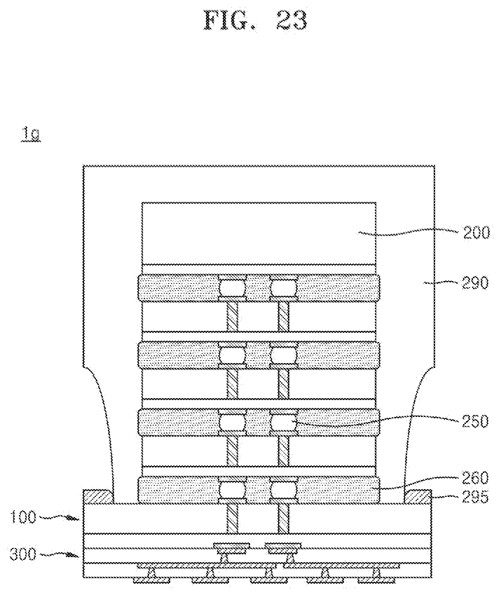

Referring to FIGS. 22 and 23, the semiconductor package 1g may be formed by cutting the second wafer W2 on the scribe lane region SL2 by using the blade BL.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a first semiconductor chip;
at least one second semiconductor chip on a top surface of the first semiconductor chip;
a molding layer on the at least one second semiconductor chip; and
a marking layer on at least one side of the molding layer, the marking layer comprising a hydrophobic material,
wherein inner sidewalls of the marking layer contact a lower portion of sidewalls of the molding layer.

2. The semiconductor package of claim 1, wherein the marking layer comprises a fluorocarbon layer.

3. The semiconductor package of claim 1, wherein the molding layer exposes the marking layer.

4. The semiconductor package of claim 1, wherein a width of the marking layer ranges from 10 micrometers to 500 micrometers.

5. The semiconductor package of claim 1, wherein a thickness of the marking layer ranges from 10 angstroms to 5000 angstroms.

6. The semiconductor package of claim 1, wherein the marking layer surrounds the molding layer when viewed in a plan view, and
wherein outer sidewalls of the marking layer are coplanar with sidewalls of the first semiconductor chip.

7. The semiconductor package of claim 1, wherein the first semiconductor chip has a first width in a first horizontal direction, and
wherein the molding layer has a second width smaller than the first width in the first horizontal direction.

8. The semiconductor package of claim 1, wherein the marking layer is on edge regions of the first semiconductor chip, and
wherein a top surface of the molding layer is at a higher level than a top surface of the marking layer in a vertical direction.

9. The semiconductor package of claim 1, wherein the first semiconductor chip has a first width in a first horizontal direction,
wherein a top surface of the molding layer has a second width equal to the first width in the first horizontal direction, and
wherein a bottom surface of the molding layer has a third width smaller than the second width in the first horizontal direction.

10. The semiconductor package of claim 1, wherein the marking layer comprises a plurality of marking layers on a peripheral region of the first semiconductor chip and spaced apart from each other, and
wherein inner sidewalls of each of the plurality of marking layers and a sidewall of the molding layer contact each other.

11. A semiconductor package comprising:
a first semiconductor chip;
a plurality of second semiconductor chips on a top surface of the first semiconductor chip;
a marking layer on peripheral regions of the top surface of the first semiconductor chip, surrounding the plurality of second semiconductor chips when viewed in a plan view, and spaced apart from the plurality of second semiconductor chips; and
a molding layer on the plurality of second semiconductor chips and comprising sidewalls contacting inner sidewalls of the marking layer,
wherein a level of a top surface of the marking layer is lower than a level of the top surface of the molding layer in a vertical direction.

12. The semiconductor package of claim 11, wherein the marking layer comprises a fluorocarbon layer, and
wherein a surface of the marking layer has hydrophobic characteristics.

13. The semiconductor package of claim 11, wherein a thickness of the marking layer ranges from 10 angstroms to 5000 angstroms, and
wherein a width of the marking layer ranges from 10 micrometers to 500 micrometers.

14. The semiconductor package of claim 11, wherein the marking layer surrounds the molding layer when viewed in a plan view, and
wherein outer sidewalls of the marking layer are coplanar with sidewalls of the first semiconductor chip.

15. The semiconductor package of claim 11, wherein the first semiconductor chip has a first width in a first horizontal direction, and
wherein the molding layer has a second width smaller than the first width in the first horizontal direction.

16. The semiconductor package of claim 11, wherein the first semiconductor chip has a first width in a first horizontal direction,
wherein a top surface of the molding layer has a second width equal to the first width in the first horizontal direction, and
wherein a bottom surface of the molding layer has a third width smaller than the second width in the first horizontal direction.

17. The semiconductor package of claim 11, wherein the marking layer comprises a plurality of marking layers on a peripheral region of the first semiconductor chip and spaced apart from each other, and
wherein inner sidewalls of the each of the plurality of marking layers and a sidewall of the molding layer contact each other.

18. A semiconductor package comprising:
a redistribution layer (RDL) interposer;
a buffer chip comprising a first substrate and a plurality of first through electrodes at least partially penetrating through the first substrate, an active surface of the first substrate facing the RDL interposer and in contact with the RDL interposer;
a plurality of memory cell chips respectively comprising a second substrate and a plurality of second through electrodes at least partially penetrating through the second substrate, the plurality of memory cell chips being sequentially on the buffer chip, such that an active surface of the second substrate faces the buffer chip;
a plurality of front surface connection pads on bottom surfaces of the plurality of memory cell chips;
a plurality of rear surface connection pads on an inactive surface of the first substrate and an inactive surface of the second substrate;
a plurality of chip connection terminals between the plurality of front surface connection pads and the plurality of rear surface connection pads;
an insulating adhesive layer between the buffer chip and the plurality of memory cell chips;
a molding layer surrounding the plurality of memory cell chips and the insulating adhesive layer; and
a marking layer on at least one side of the molding layer on the buffer chip and comprising a hydrophobic material.

19. The semiconductor package of claim 18, wherein the marking layer comprises a fluorocarbon layer, and
wherein a surface of the marking layer has hydrophobic characteristics.

20. The semiconductor package of claim 18, wherein the buffer chip has a first width in a first horizontal direction, and
wherein the molding layer has a second width smaller than the first width in the first horizontal direction.
